(19) United States
(12) Patent Application Publication
(10) Pub. No.: US 2009/0309106 A1
(43) Pub. Date: Dec. 17, 2009

(54) LIGHT-EMITTING DEVICE MODULE WITH A SUBSTRATE AND METHODS OF FORMING IT

(76) Inventor: Shen-Nan Tong, Xiamen City (CN)

Correspondence Address: LEWIS, BRISBOIS, BISGAARD & SMITH LLP, 221 NORTH FIGUEROA STREET, SUITE 1200, LOS ANGELES, CA, 90012, US

(21) Appl. No.: 11/916,011

(22) PCT Filed: May 22, 2006
(86) PCT No.: PCT/US06/19827

§ 371 Date: Nov. 29, 2007

(30) Foreign Application Priority Data
Jun. 3, 2005 (CN) 200520083962.4

(51) Int. Cl. H01L 33/00

(52) U.S. Cl. 257/88; 257/98; 257/100; 257/E33.059

(57) ABSTRACT

A light-emitting device module comprising a substrate, a light-emitting device chip and a heat-dissipating unit. The substrate has a cavity formed in the surface, has an insulator layer and metal layers, with layers of metal on the top and bottom surfaces. The light-emitting device chip is placed inside the cavity and is bonded onto the top metal layer of the substrate. The electrodes of the device chip are wired-bonded to electrodes formed on the top metal layer of the substrate. The cavity is filled with an encapsulating material to encapsulate the device chip. A heat-dissipating unit is bonded onto the bottom metal layer of the substrate.

### FIELD OF THE INVENTION

The present invention relates to a light-emitting device module and, more particularly, to a light-emitting device module having a substrate with a cavity formed on the surface.

### TECHNICAL BACKGROUND

A light-emitting diode (LED) is a semiconductor device that emits narrow-spectrum light when electrically biased in one direction. With their varying color, low power consumption, durability, small compactness and being non-hazardous and environment-friendly, light-emitting diodes have gained widespread application for a variety of lighting and illumination uses. Their useful life is much longer than most other light sources. However, conventional light-emitting diodes commonly suffer from their inability to dissipate the heat produced. This has a detrimental effect on their luminous efficacy. Considerable resources have been devoted to the research of light-emitting devices, in an effort to improve their thermal management and further enhance their luminous efficacy.

The conventional method of dissipating the heat generated by a light-emitting device is to bond the device chip onto a metal reflector with a thermal, conductive paste or silicone. The electrodes on the device chip are then wire-bonded to a printed circuit board and finally the device chip is encapsulated with epoxy to complete the packaging process. When in usage, a light-emitting device formed on a printed circuit board is normally bonded onto an aluminum plate, which acts as a thermal conductor for the heat generated within the device chip. Due to the excessive heat generated by the device chip and the limited heat-dissipation by the module, a considerable amount of heat is accumulated, which deteriorates both the luminous efficacy and the reliability of the light-emitting device.

The present invention provides a light-emitting device module having a substrate with a cavity formed on the surface, thereby overcoming many of the thermal problems encountered by conventional light-emitting device modules.

### SUMMARY OF THE INVENTION

It is therefore the objective of the present invention to provide a light-emitting device module having a substrate with a cavity formed on its surface, which dissipates heat more effectively and results in the increase of the luminosity.

The present invention consists of a substrate, a light-emitting device chip and a heat-dissipating unit. The substrate has a cavity formed on its surface and has a structure of insulator and metal, with layers of metal formed on both the top and bottom surfaces. The light-emitting device chip is placed inside the cavity and is bonded onto a metal layer of the substrate. The electrodes on the device chip are wire-bonded to the conducting metal layer of the substrate. The cavity is filled with an encapsulating material, such as silicone or epoxy, to encapsulate the device chip. The inside surface of the cavity is coated with a reflecting metal to converge the light emitting from the device chip.

The cavity on the substrate surface can be fabricated in the form of dam-shaped configuration in order to save manufacturing costs.

Depending on the desired brightness, varying numbers of device chips can be placed inside the cavity, either in linear, matrix, array or other forms of arrangements. It is also possible to form multiple numbers of cavities on the substrate surface, either in linear, matrix, array or other forms of arrangements.

The above-mentioned device chip can emit either red, yellow, blue, white or light of a different color.

The above-mentioned heat-dissipating unit can either be a passive unit, such as plates with various configurations or an active unit such as a heat pipe or fan.

The advantages of the present invention can be realized in terms of the performance and the manufacturing cost of the device module. The brightness of the device module can be improved due to the convergence of lights by the reflecting metal of the reflector. In addition, heat dissipation can also be enhanced due to the direct thermal contact between the metal layer of the substrate and the heat-dissipating unit. The flexibility of varying the numbers of device chips and cavities also makes the manufacturing of the present invention more cost-effective and its usage more handy.

### BRIEF DESCRIPTION OF THE DRAWINGS

The foregoing, and additional objects and advantages of the present invention will become apparent to those of skill in the art from the following description of a preferred embodiment thereof, taken in conjunction with the accompanying drawings, in which:

FIG. 1 is a diagrammatic, cross-sectional, side view of the light-emitting device module, showing the substrate, the device chip and the heat-dissipating unit employing the concept of the present invention.

FIG. 2 is a diagrammatic, cross-sectional, side view of the light-emitting device module showing the structure, with a dam-shaped cavity on the surface, employing the concept of the present invention.

FIG. 3(a) is a diagrammatic, top view and FIG. 3(b) is a cross-sectional, side view of the light-emitting device module showing the matrix array arrangement, employing the concept of the present invention.

FIGS. 4, 5 and 6 are diagrammatic, top and cross-sectional side views of various configurations of the light-emitting device modules employing the concept of the present invention.

### DESCRIPTION OF THE PREFERRED EMBODIMENT

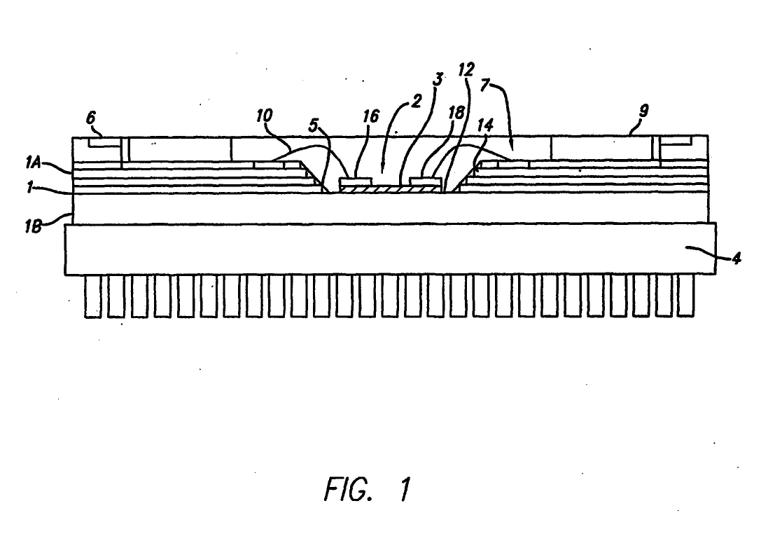

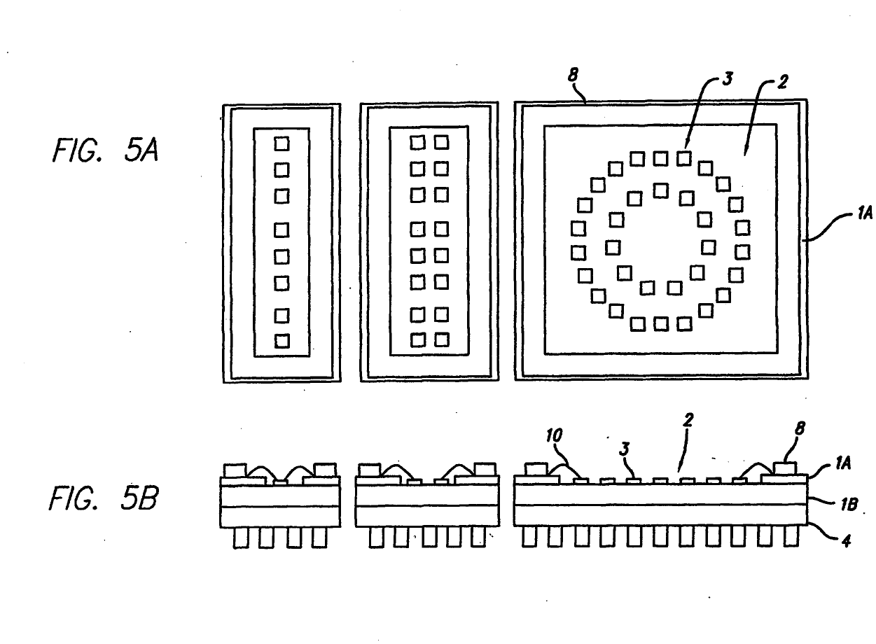

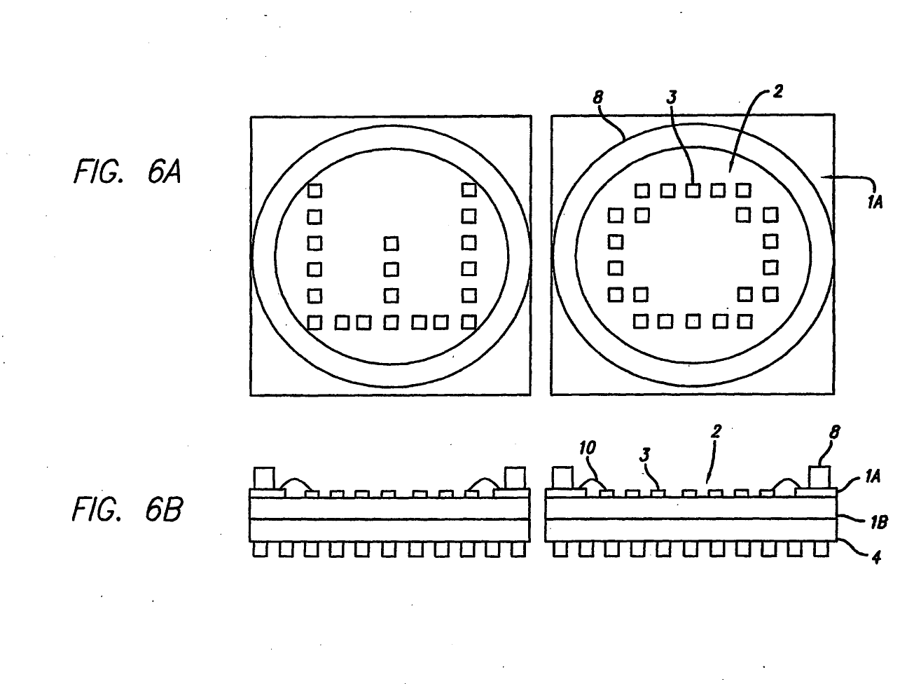

Referring now to FIGS. 1 to 6, 1 is the substrate, 1(A) is the insulating layer in the substrate, made of plastic, ceramic or other insulator materials. 1(B) is the metal layer in the substrate made of a high thermal performance material, such as copper alloy or aluminum alloy and 2 is the cavity. 3 is the device chip, 4 is the heat-dissipating unit, 5 is the reflecting metal, 6 is the electrical conducting metal layer, 7 is the encapsulating material, 8 is the dam-shaped cavity and 9 is the insulating layer, made of plastic, ceramic or other insulating materials.

The present invention provides a light-emitting device module having a substrate with a cavity on its surface. The present invention will be described below in detail with reference to the accompanying drawings. The same reference numerals denote the same parts throughout the drawings.

As shown in FIGS. 1 through 6, 1(A) is an insulating layer of the substrate 1 and 1(B) is a metal layer of the substrate 1. A cavity 2 is formed on the substrate surface. The bottom surface 12 of the cavity 2 upon which the device chips 3 are placed, occupies a portion of the metal layer 1(B) surface. A heat-dissipating unit 4 is bonded onto the bottom metal surface 1(B) of the substrate 1. The inside surface 14 of cavity 2 is coated with reflecting metal 5. The electrodes 16, 18 on the device chip 3 are bonded by wires 10 to a metal layer 6 of substrate 1.

The side wall 14 of cavity 2, formed as a dam-shaped configuration, forms a slope relative to the bottom surface of cavity 2. With reflecting metal 5 on its surface, the side wall 14 serves to converge the light emitted randomly from device chip 3, thereby enhancing the brightness of the light-emitting device.

The metal layer 6 onto which bonding-wires 10 are bonded, extends through a hole in insulating layer 9, to the outer surface of the module, thereby facilitating the electrical connection of the device chip 3 from the outer surface of the module.

Cavity 2 is filled with encapsulating epoxy 7 to protect device chip 3 and also to form an optical lens to converge the light emitting from device chip 3.

The area of the metal surface 1(B) of the substrate 1, upon which device chip 3 is bonded, undergoes chemical treatment to remove its surface oxides, to facilitate the heat-dissipation of the device chip 3.

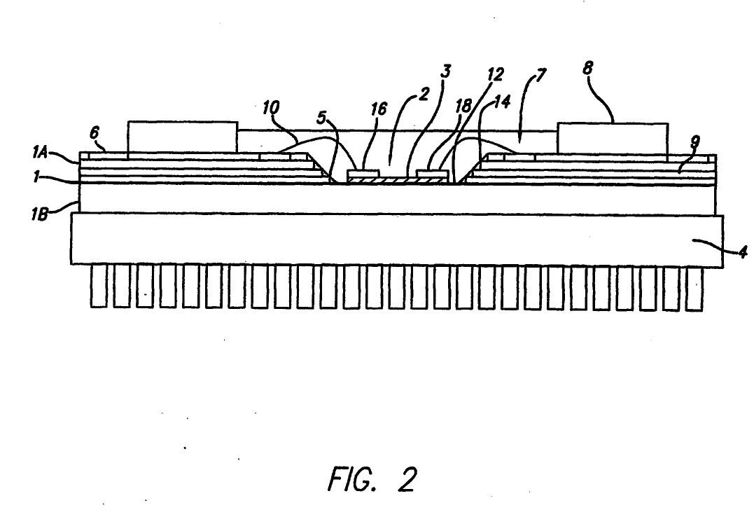

Referring to FIG. 2, a dam-shaped configuration 8 is formed upon the top metal layer 6 and is filled with encapsulating epoxy 7. In comparison with the module depicted in FIG. 1, this embodiment simplifies the manufacturing process and thereby reduces the overall cost of the device.

The number of device chips 3 inside cavity 2 can be single or multiple. Their arrangement can be linear, matrix, array or other forms of configuration. The number of cavities 2 on the substrate surface can be single or multiple. Their arrangement can be linear, matrix, array or other forms of configuration.

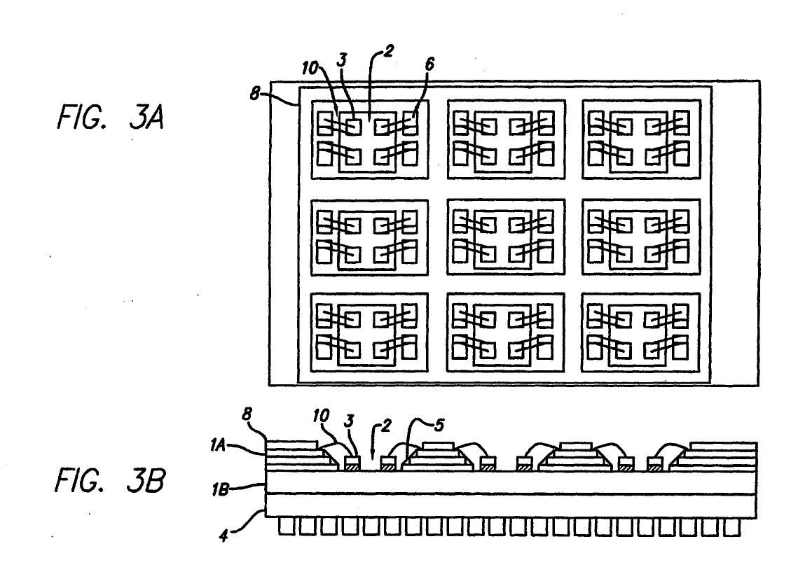

FIG. 3(a) is a diagrammatic, top view and FIG. 3(b) is a cross-sectional, side view of the light-emitting device module showing the matrix array arrangement, using multiple light-emitting device modules. Each of the units is identical and comprises four light emitting device chips 3, which may be of different colors, such as red, green and blue. The device chips 3 are contained in a cavity 2. Each light emitting device 3 is electrically bonded by wires 10 to a metal layer 6 of substrate 1. A dam structure 8, as shown in FIG. 2, surrounds cavity 2. FIG. 3B shows the insulation layer 1A, the metal layer 1B and the heat dissipation unit 4. Also shown is the reflector 5.

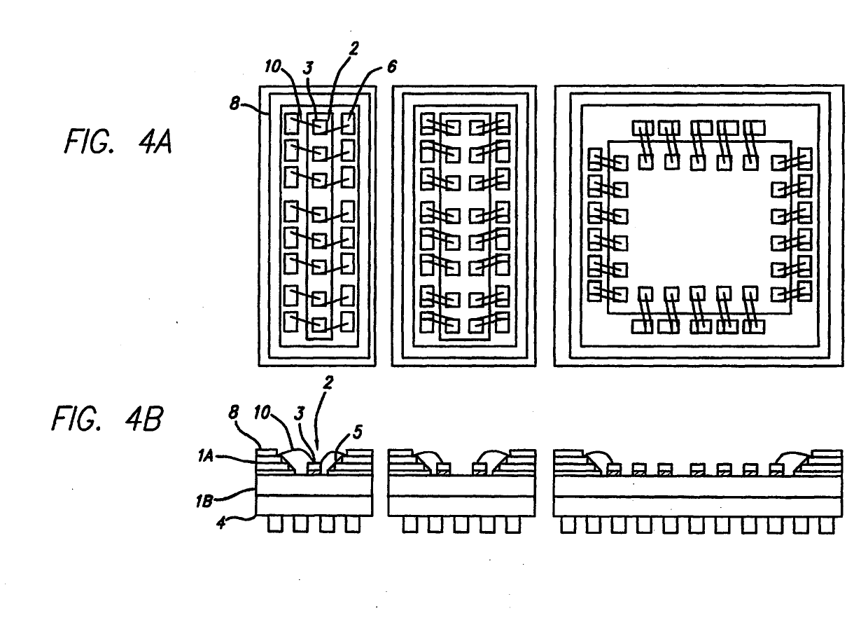

FIGS. 4, 5 and 6 are diagrammatic, top and cross-sectional side views of various configurations using multiple light-emitting device modules showing the same components as set forth in FIGS. 3A and 3B.

The device chip 3 can be a chip emitting red, yellow, blue, green, white or light of different color.

The heat-dissipating unit 4 bonded to the bottom metal surface 1(B) of the substrate 1 can be a passive unit in the form of a plate or other forms or configurations, or can also be an active unit, in the form of heat pipe or fan.

The conducting metal layer 6 of the substrate 1, upon which the bonding wires 10 of the electrodes of the device chip 3 are bonded, extends to the outer surface of substrate 1, thereby facilitating the electrical connection of the device module to any other device or component. Substrate 1 can be formed with a single metal layer on the top and bottom or by a laminated structure with multi-metal layers embedded within the insulator layer, however the single metal layer dissipates the heat more effectively than a laminated substrate. The insulator layer in the substrate can be made of plastic, ceramic or high polymer materials.

### INDUSTRIAL APPLICABILITY

LED's are commonly used for lightweight message displays, status indicators, clusters in traffic signals, calculator displays and car indicator lights, as well as many other applications.

Having thus described the invention, I claim:

1. A light-emitting device module comprising:
a substrate having a cavity formed on its top surface;
said substrate having a laminated insulator layer, with layers of metal on the top and bottom surfaces of said laminated insulator layer;
a light-emitting device chip located in said cavity of the substrate;
a heat-dissipating unit;
wherein said light-emitting device chip is wired-bonded to electrodes on the top metal surface of said substrate;
wherein said light-emitting device is thermally connected to a metal layer of said substrate and said heat-dissipating unit; and
wherein said cavity is filled with an encapsulating material to encapsulate the light-emitting device chip.

2. The light-emitting device of claim 1, wherein said cavity is lined with a reflecting metal coating.

3. The light-emitting device of claim 1, wherein said cavity has a dam-shaped configuration.

4. The light-emitting device of claim 1, comprising a plurality of light-emitting device chips.

5. The light-emitting device of claim 4, wherein said plurality of light-emitting device chips are arranged in linear, matrix or array forms.

6. The light-emitting device of claim 1, comprising a plurality of cavities.

7. The light-emitting device of claim 6, wherein said plurality of cavities are arranged in linear, matrix, or array forms.

8. The light-emitting device of claim 1, wherein said light-emitting device chip emits red, yellow, blue, green, white or other light.

9. The light-emitting device of claim 1, wherein said heat-dissipating unit is a passive unit or an active unit.

10. The light-emitting device of claim 9 wherein the heat-dissipating unit is one or more plates.

11. The light-emitting device of claim 9 wherein the heat-dissipating unit is a pipe or a fan.

12. The light-emitting device of claim 1 wherein the metal layer is a single metal layer or a multi-layered laminate.

13. The light-emitting device of claim 1 in which the metal layers of the substrate are composed of high thermal performance material.

14. The light-emitting device of claim 1 in which the insulating layers of the substrate are composed of plastic, ceramic or high polymer materials.

15. The light-emitting device of claim 1 in which the reflective metal is composed of plated silver, aluminum, copper or gold.

16. The light-emitting device of claim 1 in which the encapsulating material is silicone or epoxy.

17. The light-emitting device of claim 13 in which the high thermal performance material is copper alloy or aluminum alloy.
